(19) United States
(12) Patent Application Publication
(10) Pub. No.: US 2012/0034379 A1
(43) Pub. Date: Feb. 9, 2012

(54) COATING METHOD

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/904,142

(22) Filed: Oct. 13, 2010

(30) Foreign Application Priority Data
Aug. 3, 2010 (TW) 99125692

(51) Int. Cl. C23C 16/44; C23C 16/06

(52) U.S. Cl. 427/248.1; 427/282

(57) ABSTRACT

A coating method includes following steps. A workpiece having a flat surface is provided. The surface includes a coating region and a pattern region. A tape mask having a through hole, whose shape and size conforms to the pattern region, is attached onto the flat surface of workpiece to cover the coating region, thus exposing the pattern region. A screen printing stencil is placed on the tape mask. Ink is spread over the screen printing stencil printing stencil, and squeezed into the through hole over the pattern region. The ink is solidified. The tape mask is removed from the workpiece. A metallic coating is formed on the coating region of the flat surface and the solidified ink on the pattern region is removed.

### BACKGROUND

1. Technical Field

The present disclosure relates to coating technology, and particularly, to a coating method for forming a metallic coating on a workpiece, the workpiece having an uncoated portion conforming to a predetermined pattern.

2. Description of Related Art

Electronic products, such as computers, cell phones, and digital cameras often display a logo or other graphic on a predetermined region of an outer surface thereof, and are coated with a film layer formed on the residual region of the outer surface. Accordingly, prior to coating the shell, a template covers the predetermined region for the graphic. The template has the same dimension and configuration as the graphic. After coating the film layer on the residual region of the outer surface, the template is removed. However, edges of the target region are unclear. As a result, precision of the graphic formed subsequently may fail to meet predetermined requirements. Thus, a coating method is desired to overcome the limitations described.

### BRIEF DESCRIPTION OF THE DRAWINGS

Many aspects of the present coating method can be better understood with reference to the following drawings. The components in the drawings are not necessarily drawn to scale, the emphasis instead being placed upon clearly illustrating the principles of the presentment coating method. Moreover, in the drawings, like reference numerals designate corresponding parts throughout the views.

FIG. 1 is an isometric view of a workpiece, a tape mask and a screen printing stencil employed in a method according to an embodiment of the present disclosure.

FIG. 2 shows the tape mask laminated onto the workpiece.

FIG. 3 shows applying ink onto the workpiece the tape mask.

FIG. 4 shows the ink being solidified on the workpiece.

FIG. 5 shows a metallic film layer formed on the workpiece.

FIG. 6 shows the resultant coated workpiece after removing the ink.

### DETAILED DESCRIPTION

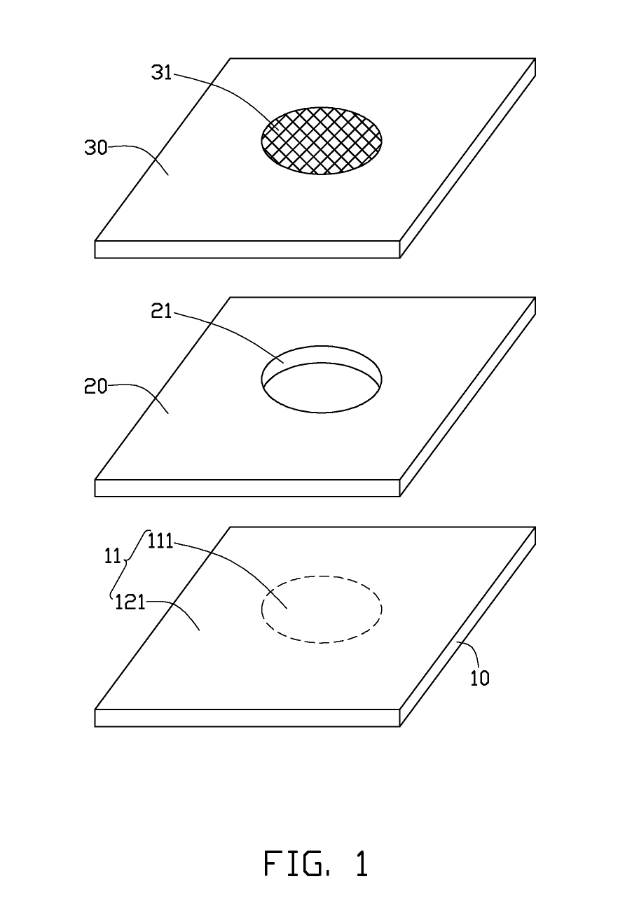

FIG. 1 shows a workpiece 10, a tape mask 20 and a screen printing stencil 30 in accordance with an exemplary embodiment. The workpiece 10 and the tape mask 20 can be glass, silicon, quartz, silicon carbide, plastic, metal, metal alloy, or stainless steel. In the present embodiment, the workpiece 10 is a plastic plate for manufacturing a shell of portable computer, and the tape mask 20 is polyimide film. The workpiece 10 includes a flat outer surface 11. The outer surface 11 includes a coating region 121 and a pattern region 111 for forming a graphic of the portable computer. The tape mask 20 has a through hole 21 of the same dimension and configuration as the graphic. The screen printing stencil 30 includes a mesh region 31 of the same dimension and configuration as the graphic.

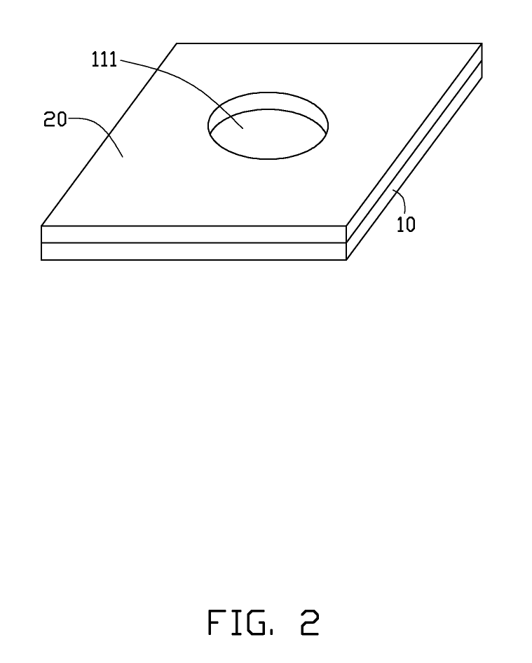

Referring to FIGS. 1 and 2, the tape mask 20 is laminated on the coating region 121 of the workpiece 10. The tape mask 20 can be directly adhered on the coating region 121 in such a manner that the through hole 21 is aligned with the pattern region 111, and the through hole 21 is gas-proof with the coating region 121.

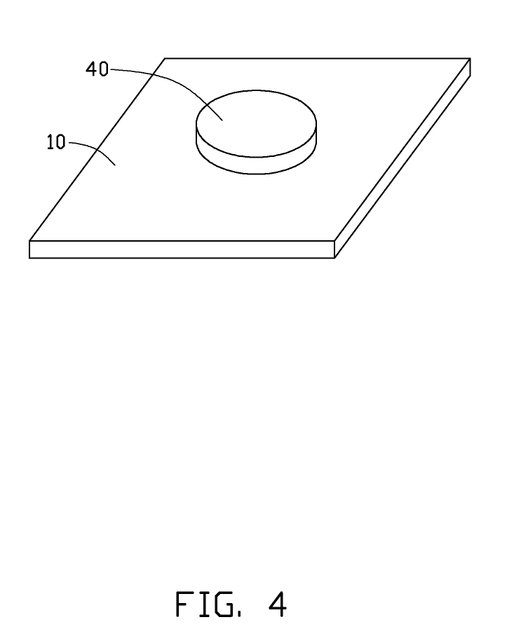

Referring to FIGS. 1 to 4, the screen printing stencil 31 is placed on the tape mask 20 with the mesh region 31 aligned with the through hole 21. A scratching tool 32 is employed to spread the ink 40 over the screen printing stencil 31 and squeeze the ink 40 into the through hole 21 over the pattern region 111. The ink 40 can be solidified by UV irradiation and easily stripped from the workpiece 10.

The ink 40 is then solidified. It is understood that the solidified ink 40 has the same dimension and configuration as the through hole 21, and entirely covers the pattern region 111.

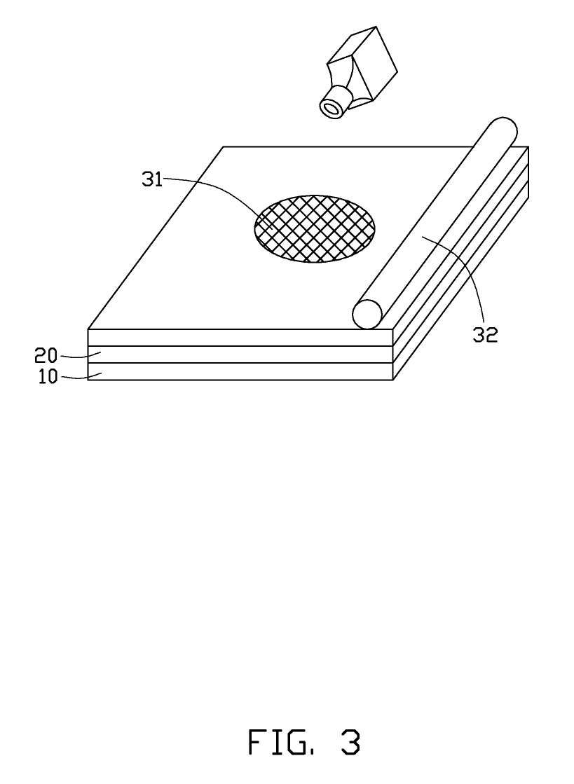

Referring to FIGS. 3 to 5, the tape mask 20 is removed, and a metallic film layer 50 is formed on the coating region 121 using a typical coating process, such as physical vapor deposition, chemical vapor deposition, laser assisted evaporation or ion polymerization deposition.

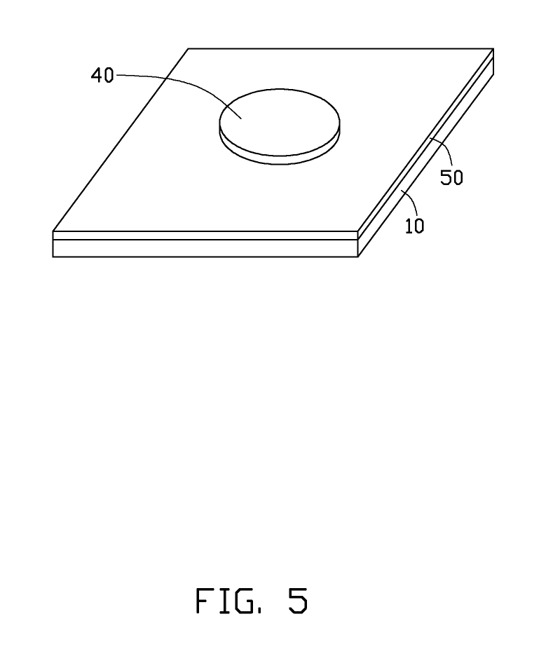

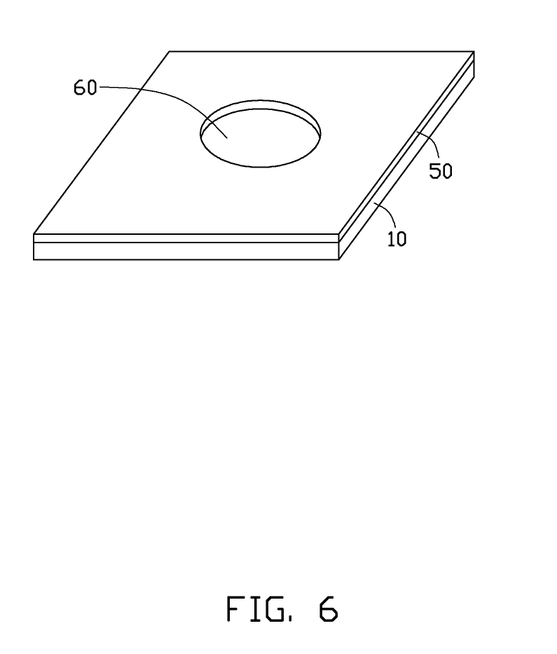

Referring to FIGS. 5 and 6, the solidified ink 40 is removed, thereby forming a pattern 60 on the pattern region 111. The solidified ink 40 can be directly stripped from the workpiece 10 or dissolved with chemical agents. It is understood that the edge of the pattern 60 is consistent with the edge of the through hole 21. Therefore, the edge of the pattern 60 is clear.

The embodiments described are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A coating method, comprising:
providing a workpiece, the workpiece comprising a flat surface including a coating region and a pattern region;
attaching a tape mask on the flat surface of workpiece to cover the coating region, the tape mask comprising a through hole having a shape and size conforming to the pattern region, thus exposing the pattern region;
placing a screen printing stencil on the tape mask;
spreading ink over the screen printing stencil printing stencil, and squeezing the ink into the through hole over the pattern region;
solidifying the ink;
removing the tape mask from the workpiece;
forming a metallic coating on the coating region of the flat surface; and
removing the solidified ink on the pattern region.

2. The coating method of claim 1, wherein the screen printing stencil comprises an open mesh region having a shape and size conforming to the through hole.

3. The coating method of claim 1, wherein the workpiece is comprised of metal or metal alloy.

4. The coating method of claim 1, wherein the metallic coating is formed on the coating region using a physical vapor deposition process.

5. The coating method of claim 1, wherein the tape mask is a polyimide film.
